(19) United States
(12) Patent Application Publication
(10) Pub. No.: US 2023/0275134 A1
(43) Pub. Date: Aug. 31, 2023

(54) SILICON CARBIDE DEVICE

(71) Applicant: SUZHOU ORIENTAL SEMICONDUCTOR CO., LTD., Jiangsu (CN)

(72) Inventors: Yi GONG, Jiangsu (CN); Lei LIU, Jiangsu (CN); Wei LIU, Jiangsu (CN); Rui WANG, Jiangsu (CN)

(21) Appl. No.: 17/614,259

(22) PCT Filed: Nov. 20, 2020
(86) PCT No.: PCT/CN2020/130599

§ 371 Date: Nov. 24, 2021

(30) Foreign Application Priority Data
Nov. 16, 2020 (CN) 202011280134.5

(51) Int. Cl. H01L 29/417; H01L 29/16; H01L 29/78

(52) U.S. Cl. CPC H01L 29/41741; H01L 29/1608; H01L 29/7813

(57) ABSTRACT

The silicon carbide device includes a gate trench, a source trench, a gate, a source and a p-type well region. The gate trench and the source trench are disposed in a silicon carbide substrate and alternately spaced apart. The gate disposed in the gate trench is isolated from a second n-type silicon carbide layer by a first insulating layer, and the gate is isolated from a p-type silicon carbide layer and a third n-type silicon carbide layer by a second insulating layer. The source disposed in the source trench is connected to the p-type silicon carbide layer and the third n-type silicon carbide layer, and the source is isolated from the second n-type silicon carbide layer by a third insulating layer. The p-type well region is disposed at a bottom of the source trench, where the p-type well region is connected to the source.

### CROSS REFERENCE TO RELATED APPLICATION

This is a national stage application filed under 37 U.S.C. 371 based on International Patent Application No. PCT/CN2020/130599, filed Nov. 20, 2020, which claims priority to Chinese Patent Application No. 202011280134.5 filed Nov. 16, 2020, the disclosures of which are incorporated herein by reference in their entireties.

### TECHNICAL FIELD

The present application belongs to the technical field of semiconductor devices, for example, relates to a silicon carbide device.

### BACKGROUND

Silicon carbide has many characteristics that are different from traditional silicon semiconductor materials. The band gap of silicon carbide is 2.8 times that of silicon, and the insulation breakdown field strength of silicon carbide is 5.3 times that of silicon. Therefore, in a field of high-voltage power devices, compared with silicon materials, a thinner epitaxial layer may be used in a silicon carbide device so that while the silicon carbide device has the same voltage withstand level as a traditional silicon device, the silicon carbide device has a lower on-resistance. At present, the main problem of using silicon carbide to prepare a trench power device is that a large electric field is applied to a gate dielectric layer in a gate trench when the trench power device is in operation so that the gate is easily broken down and thus a voltage withstand level of the trench power device is affected.

### SUMMARY

The present application provides a silicon carbide device so that a risk of a gate being broken down can be reduced and a voltage withstand level of the device can be improved.

The present application provides a silicon carbide device. The silicon carbide device includes a silicon carbide substrate, a gate trench and a source trench, a gate, a source and a p-type well region.

The silicon carbide substrate includes a first n-type silicon carbide layer, a second n-type silicon carbide layer, a p-type silicon carbide layer and a third n-type silicon carbide layer, where the first n-type silicon carbide layer, the second n-type silicon carbide layer, the p-type silicon carbide layer and the third n-type silicon carbide layer are sequentially stacked.

The gate trench and the source trench are disposed in the silicon carbide substrate and alternately spaced apart, where a bottom of the gate trench and a bottom of the source trench are both disposed in the second n-type silicon carbide layer.

The gate is disposed in the gate trench, where the gate is isolated from the second n-type silicon carbide layer by a first insulating layer, and the gate is isolated from the p-type silicon carbide and the third n-type silicon carbide layer by a second insulating layer.

The source is disposed in the source trench, where the source is connected to the p-type silicon carbide layer, the source is connected to the third n-type silicon carbide layer, and the source is isolated from the second n-type silicon carbide layer at a sidewall position of the source trench by a third insulating layer.

The p-type well region is disposed in the second n-type silicon carbide layer and disposed at the bottom of the source trench, where at the bottom of the source trench, the p-type well region is connected to the source.

In an embodiment of the present application, a depth of the gate trench is the same as a depth of the source trench.

In an embodiment of the present application, a width of the source trench is greater than a width of the gate trench.

In an embodiment of the present application, a thickness of the first insulating layer is greater than a thickness of the second insulating layer.

In an embodiment of the present application, a material of the first insulating layer is at least one of silicon oxide, silicon nitride, silicon oxynitride, aluminum oxide or hafnium oxide.

In an embodiment of the present application, a material of the second insulating layer is at least one of silicon oxide, silicon nitride, silicon oxynitride, aluminum oxide or hafnium oxide.

In an embodiment of the present application, a material of the third insulating layer is at least one of silicon oxide, silicon nitride, silicon oxynitride, aluminum oxide or hafnium oxide.

In an embodiment of the present application, a material of the gate is at least one of conductive polysilicon, titanium, nickel, copper, aluminum, silver, gold, titanium nitride or tungsten.

In an embodiment of the present application, a material of the source is at least one of conductive polysilicon, titanium, nickel, copper, aluminum, silver, gold, titanium nitride or tungsten.

In the silicon carbide device of the present application, firstly, the p-type well region is disposed at the bottom of the source trench so that an electric field near the bottom of the source trench can be increased and the highest electric field can be limited at a p-n junction at the bottom of the source trench, thereby protecting the gate in the gate trench from being easily broken down and improving the voltage withstand level of the device; secondly, the first insulating layer with a larger thickness is used at the bottom of the gate trench, thereby further protecting the gate from being broken down.

### BRIEF DESCRIPTION OF DRAWINGS

FIG. 1 is a sectional view of a silicon carbide device according to an embodiment of the present application.

### DETAILED DESCRIPTION

Technical solutions of the present application are described completely hereinafter in conjunction with the drawings in embodiments of the present application. It is to be understood that the terms used in the present application such as “provided”, “comprising” and “including” do not exclude the presence of one or more other components or combinations thereof. Meanwhile, to illustrate the embodiments of the present application clearly, in the schematic view illustrated in DRAWINGS, thicknesses of layers and regions described in the present application are enlarged, and dimensions illustrated in the view do not represent the actual dimensions.

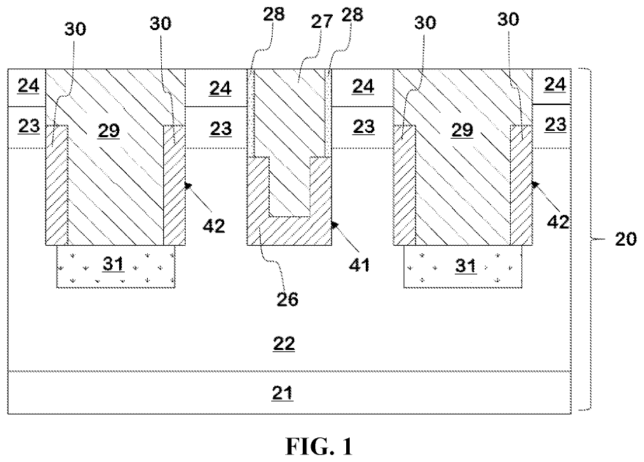

FIG. 1 is a sectional view of a silicon carbide device according to an embodiment of the present application. As shown in FIG. 1, a silicon carbide device of the present application includes a silicon carbide substrate 20 including a first n-type silicon carbide layer 21, a second n-type silicon carbide layer 22, a p-type silicon carbide layer 23 and a third n-type silicon carbide layer 24, where the first n-type silicon carbide layer 21, the second n-type silicon carbide layer 22, the p-type silicon carbide layer 23 and the third n-type silicon carbide layer 24 are sequentially stacked, where the first n-type silicon carbide layer 21 is used as an n-type drain region of the silicon carbide device.

A gate trench 41 and a source trench 42 are disposed in the silicon carbide substrate 20 and alternately spaced apart, where a bottom of the gate trench 41 and a bottom of the source trench 42 are both disposed in the second n-type silicon carbide layer 22. The number of gate trenches 41 and the number of source trenches 42 are determined by the specification of the designed silicon carbide device. In the embodiment of the present application, only one gate trench 41 and two source trenches 42 are shown as an example. A depth of the gate trench 41 may be the same as a depth of the source trench 42 so that the gate trench 41 and the source trench 42 can be simultaneously formed in the same etching process.

The p-type silicon carbide layer 23 disposed between the gate trench 41 and the source trench 42 may be used as a p-type body region of the silicon carbide device, and the third n-type silicon carbide layer 24 disposed between the gate trench 41 and the source trench 42 may be used as an n-type source region of the silicon carbide device.

A gate 27 is disposed in the gate trench 41. The gate 27 is isolated from the second n-type silicon carbide layer 22 by a first insulating layer 26. The material of the first insulating layer 26 may be at least one of silicon oxide, silicon nitride, silicon oxynitride, aluminum oxide or hafnium oxide, and the material of the gate 27 may be at least one of conductive polysilicon, titanium, nickel, copper, aluminum, silver, gold, titanium nitride or tungsten. The gate 27 is isolated from the p-type silicon carbide layer 23 and the third n-type silicon carbide layer 24 by a second insulating layer 28. The material of the second insulating layer 28 may be at least one of silicon oxide, silicon nitride, silicon oxynitride, aluminum oxide or hafnium oxide and may also be another insulating medium with a high dielectric constant. A thickness of the first insulating layer 26 may be the same as a thickness of the second insulating layer 28, and the material of the first insulating layer 26 is the same as the material of the second insulating layer 28 so that the first insulating layer 26 and the second insulating layer 28 can be formed in the same manufacturing process step. The thickness of the first insulating layer 26 may also be greater than the thickness of the second insulating layer 28, thereby protecting the gate 27 in the gate trench 41 from being easily broken down.

A source 29 is disposed in the source trench 42. The source 29 is connected to the p-type silicon carbide layer 23, the source 29 is connected to the third n-type silicon carbide layer 24, and the source 29 is isolated from the second n-type silicon carbide layer 22 at a sidewall position of the source trench 42 by a third insulating layer 30. The material of the third insulating layer 30 may be at least one of silicon oxide, silicon nitride, silicon oxynitride, aluminum oxide or hafnium oxide, and the material of the source 29 may be at least one of conductive polysilicon, titanium, nickel, copper, aluminum, silver, gold, titanium nitride or tungsten. The material of the third insulating layer 30 may be the same as the material of the first insulating layer 26. In this manner, the third insulating layer 30 and the first insulating layer 26 can be formed in the same manufacturing process step, thereby simplifying the manufacturing process of the silicon carbide device.

A width of the source trench 42 may be greater than a width of the gate trench 41 so that the first insulating layer 26 in the gate trench 41 can be formed more easily, thereby simplifying the manufacturing process of the silicon carbide device of the present application.

A p-type well region 31 is disposed in the second n-type silicon carbide layer 22 and disposed at the bottom of the source trench 42, where at the bottom of the source trench 42, the p-type well region 31 is connected to the source 29. The p-type well region 31 and the second n-type silicon carbide layer 22 form a p-n junction structure so that an electric field near the bottom of the source trench 42 can be increased and the highest electric field in the silicon carbide device can be limited at the p-n junction at the bottom of the source trench 42, thereby protecting the gate 27 in the gate trench 41 from being easily broken down and improving a voltage withstand level of the device.

What is claimed is:

1. A silicon carbide device, comprising:
a silicon carbide substrate comprising a first n-type silicon carbide layer, a second n-type silicon carbide layer, a p-type silicon carbide layer and a third n-type silicon carbide layer, wherein the first n-type silicon carbide layer, the second n-type silicon carbide layer, the p-type silicon carbide layer and the third n-type silicon carbide layer are sequentially stacked;
a gate trench disposed in the silicon carbide substrate, and a source trench disposed in the silicon carbide substrate, wherein the gate trench and the source trench are alternately spaced apart, and a bottom of the gate trench and a bottom of the source trench are both disposed in the second n-type silicon carbide layer;
a gate disposed in the gate trench, wherein the gate is isolated from the second n-type silicon carbide layer by a first insulating layer, and the gate is isolated from the p-type silicon carbide layer and the third n-type silicon carbide layer by a second insulating layer;
a source disposed in the source trench, wherein the source is connected to the p-type silicon carbide layer, the source is connected to the third n-type silicon carbide layer, and the source is isolated from the second n-type silicon carbide layer at a sidewall position of the source trench by a third insulating layer; and
a p-type well region disposed in the second n-type silicon carbide layer and disposed at the bottom of the source trench, wherein at the bottom of the source trench, the p-type well region is connected to the source.

2. The silicon carbide device of claim 1, wherein a depth of the gate trench is the same as a depth of the source trench.

3. The silicon carbide device of claim 1, wherein a width of the source trench is greater than a width of the gate trench.

4. The silicon carbide device of claim 1, wherein a thickness of the first insulating layer is greater than a thickness of the second insulating layer.

5. The silicon carbide device of claim 1, wherein a material of the first insulating layer is at least one of silicon oxide, silicon nitride, silicon oxynitride, aluminum oxide or hafnium oxide.

6. The silicon carbide device of claim 1, wherein a material of the third insulating layer is at least one of silicon oxide, silicon nitride, silicon oxynitride, aluminum oxide or hafnium oxide.

7. The silicon carbide device of claim 1, wherein a material of the second insulating layer is at least one of silicon oxide, silicon nitride, silicon oxynitride, aluminum oxide or hafnium oxide.

8. The silicon carbide device of claim 1, wherein a material of the gate is at least one of conductive polysilicon, titanium, nickel, copper, aluminum, silver, gold, titanium nitride or tungsten.

9. The silicon carbide device of claim 1, wherein a material of the source is at least one of conductive polysilicon, titanium, nickel, copper, aluminum, silver, gold, titanium nitride or tungsten.
